(19) United States
(12) Patent Application Publication
(10) Pub. No.: US 2012/0256198 A1
(43) Pub. Date: Oct. 11, 2012

(54) LED PACKAGE STRUCTURE FOR INCREASING THE LIGHT UNIFORMING EFFECT

(75) Inventors: CHIN-KAI HUANG, YILAN COUNTY (TW); CHIH-WEI HSIEH, TAIPEI CITY (TW); CHIA-LUNG HSUEH, YILAN COUNTY (TW); SHIH-MIN WU, TAOYUAN COUNTY (TW); DAWSON LIU, TAIPEI CITY (TW)

(73) Assignee: LUSTROUS TECHNOLOGY LTD., NEW TAIPEI CITY (TW)

(21) Appl. No.: 13/238,360

(22) Filed: Sep. 21, 2011

(30) Foreign Application Priority Data
Apr. 6, 2011 (TW) 100111830

(51) Int. Cl. H01L 33/08

(52) U.S. Cl. 257/88; 257/E33.012

(57) ABSTRACT

A LED package structure for increasing the light uniforming effect includes a substrate unit, a light emitting unit, a first package unit, and a second package unit. The substrate unit includes at least one substrate body. The light emitting unit includes at least one light emitting element disposed on the at least one substrate body and electrically connected to the at least one substrate body. The first package unit includes a first package resin body formed on the at least one substrate body to cover the at least one light emitting element. The second package unit includes a second package resin body formed on the at least one substrate body to cover the first package resin body. The second package resin body is a light uniforming resin body having a light diffusing material mixed therein, and the second package resin body has an exposed light uniforming surface formed thereon.

### BACKGROUND OF THE INVENTION

1. Field of the Invention

The instant disclosure relates to a LED package structure, and more particularly, to a LED package structure for increasing the light uniforming effect.

2. Description of Related Art

The invention of the lamp greatly changes the style of building construction and the lifestyle of human beings, allowing people to work during the night. Traditional lighting devices such as lamps that adopt incandescent bulbs, fluorescent bulbs, or power-saving bulbs have been generally well-developed and used intensively for indoor illumination.

Moreover, compared to the newly developed light-emitting-diode (LED) lamps, these traditional lamps have the disadvantages of quick attenuation, high power consumption, high heat generation, short service life, high fragility, and being not recyclable. Thus, various high-powered LED structures are created to replace the traditional light sources.

### SUMMARY OF THE INVENTION

One aspect of the instant disclosure relates to a LED package structure for increasing the light uniforming effect of the illumination of the LED package structure.

One of the embodiments of the instant disclosure provides a LED package structure for increasing the light uniforming effect, comprising: a substrate unit, a light emitting unit, a first package unit, and a second package unit. The substrate unit includes at least one substrate body. The light emitting unit includes at least one light emitting element disposed on the at least one substrate body and electrically connected to the at least one substrate body. The first package unit includes a first package resin body formed on the at least one substrate body to cover the at least one light emitting element. The second package unit includes a second package resin body formed on the at least one substrate body to cover the first package resin body, wherein the second package resin body is a light uniforming resin body having a light diffusing material mixed therein, and the second package resin body has an exposed light uniforming surface formed thereon. Hence, light beams generated by the at least one light emitting element sequentially pass through the first package resin body and the second package resin body to form an uniform light emitting region on the exposed light uniforming surface.

Furthermore, the first package resin body may be a transparent resin body formed by silicone or epoxy. The first package resin body may be a phosphor resin body formed by mixing silicone and a plurality of phosphor particles or by mixing epoxy and a plurality of phosphor particles. The second package resin body may be a light diffusing resin body formed by mixing silicon and a plurality of light diffusing particles or by mixing epoxy and a plurality of light diffusing particles. The second package resin body may be a light diffusing resin body formed by mixing silicon, a plurality of first light diffusing particles, and a plurality of second light diffusing particles or by mixing epoxy, a plurality of first light diffusing particles, and a plurality of second light diffusing particles.

Another one of the embodiments of the instant disclosure provides a LED package structure for increasing the light uniforming effect, comprising: a substrate unit, a light emitting unit, a frame unit, a first package unit, and a second package unit. The substrate unit includes at least one substrate body. The light emitting unit includes at least one light emitting element disposed on the at least one substrate body and electrically connected to the at least one substrate body. The frame unit includes a surrounding reflection frame body surroundingly disposed on the at least one substrate body to form a receiving space, wherein the surrounding reflection frame body surrounds the at least one light emitting element, thus the at least one light emitting element is received in the receiving space. The first package unit includes a first package resin body formed on the at least one substrate body to cover the at least one light emitting element, wherein the first package resin body is received in the receiving space of the surrounding reflection frame body. The second package unit includes a second package resin body received in the receiving space of the surrounding reflection frame body and disposed on the top surface of the first package resin body, wherein the second package resin body is a light uniforming resin body having a light diffusing material mixed therein, and the second package resin body has an exposed light uniforming surface formed thereon. Hence, light beams generated by the at least one light emitting element sequentially pass through the first package resin body and the second package resin body to form an uniform light emitting region on the exposed light uniforming surface.

Furthermore, the first package resin body may be a transparent resin body formed by silicone or epoxy. The first package resin body may be a phosphor resin body formed by mixing silicone and a plurality of phosphor particles or by mixing epoxy and a plurality of phosphor particles. The second package resin body may be a light diffusing resin body formed by mixing silicon and a plurality of light diffusing particles or by mixing epoxy and a plurality of light diffusing particles. The second package resin body may be a light diffusing resin body formed by mixing silicon, a plurality of first light diffusing particles, and a plurality of second light diffusing particles or by mixing epoxy, a plurality of first light diffusing particles, and a plurality of second light diffusing particles. In addition, the light diffusing particles may be made of silicon dioxide or titanium dioxide, the first light diffusing particles may be made of silicon dioxide or titanium dioxide, the second light diffusing particles may be made of silicon dioxide or titanium dioxide, and the first light diffusing particle and the second light diffusing particle can be two different light diffusing substances.

Therefore, because the second package resin body is a light uniforming resin body having a light diffusing material mixed therein, the light uniforming effect of the illumination generated from the LED package structure can be increased. In addition, the light diffusing particles may be made of silicon dioxide or titanium dioxide, the first light diffusing particles may be made of silicon dioxide or titanium dioxide, the second light diffusing particles may be made of silicon dioxide or titanium dioxide, and the first light diffusing particle and the second light diffusing particle can be two different light diffusing substances.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, cross-sectional, schematic view of the LED package structure for increasing the light uniforming effect according to the first embodiment of the instant disclosure;

FIG. 2 shows a lateral, cross-sectional, schematic view of the LED package structure for increasing the light uniforming effect according to the second embodiment of the instant disclosure;

FIG. 3 shows a lateral, cross-sectional, schematic view of the LED package structure for increasing the light uniforming effect according to the third embodiment of the instant disclosure;

FIG. 4 shows a lateral, cross-sectional, schematic view of the LED package structure for increasing the light uniforming effect according to the fourth embodiment of the instant disclosure;

FIG. 5 shows a lateral, cross-sectional, schematic view of the LED package structure for increasing the light uniforming effect according to the fifth embodiment of the instant disclosure;

FIG. 6 shows a lateral, cross-sectional, schematic view of the LED package structure for increasing the light uniforming effect according to the sixth embodiment of the instant disclosure;

FIG. 7 shows a lateral, cross-sectional, schematic view of the LED package structure for increasing the light uniforming effect according to the seventh embodiment of the instant disclosure; and

FIG. 8 shows a lateral, cross-sectional, schematic view of the LED package structure for increasing the light uniforming effect according to the eighth embodiment of the instant disclosure.

### DETAILED DESCRIPTION OF THE PREFERRED EMBODIMENTS

### First Embodiment

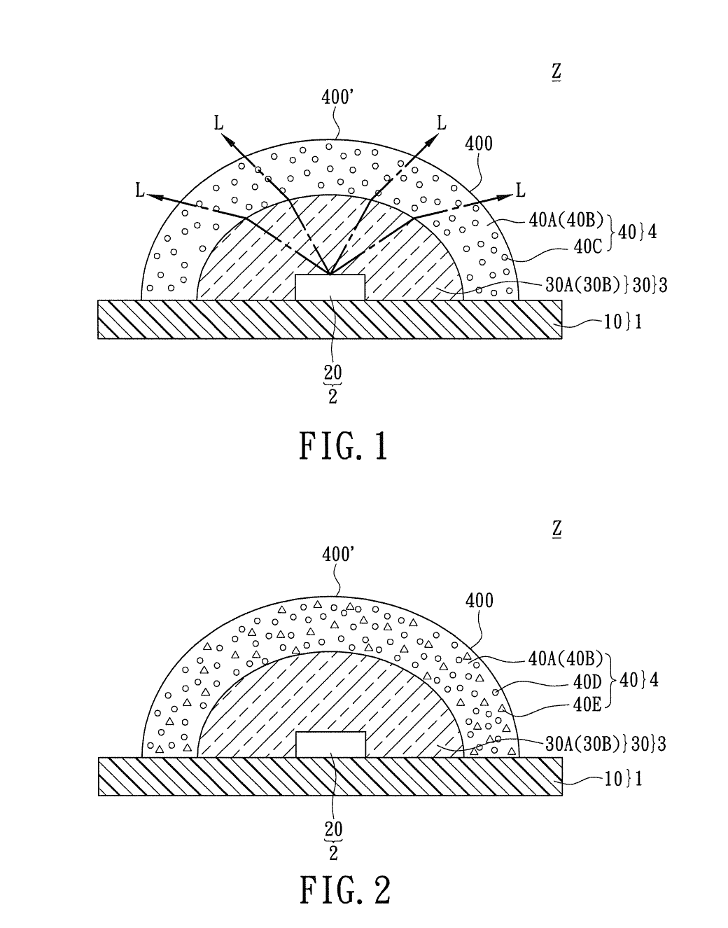

Referring to FIG. 1, where the first embodiment provides a LED package structure Z for increasing the light uniforming effect, comprising: a substrate unit 1, a light emitting unit 2, a first package unit 3, and a second package unit 4.

The substrate unit 1 includes at least one substrate body 10. For example, the at least one substrate body 10 may be a circuit substrate, and the circuit substrate has a plurality of conductive traces (not shown) formed thereon.

The light emitting unit 2 includes at least one light emitting element 20 disposed on the at least one substrate body 10 and electrically connected to the at least one substrate body 10. Of course, the first embodiment can use a plurality of light emitting elements 20 disposed on the at least one substrate body 10 and electrically connected to the at least one substrate body 10. For example, the at least one light emitting element 20 may be a blue LED bare die, and the at least one light emitting element 20 can be electrically connected to the at least one substrate body 10 by a wire-bonding manner or a flip-chip manner.

The first package unit 3 includes a first package resin body 30 formed on the at least one substrate body 10 to cover the at least one light emitting element 20. In addition, the first package resin body 30 may be a transparent resin body formed by silicone 30A or epoxy 30B according to different requirements. For example, liquid silicone or liquid epoxy can be formed on the at least one substrate body 10 to cover the at least one light emitting element 20 by adhesive dripping or press molding, and then liquid silicone or liquid epoxy can be baked (or cured) to form the solidified first package resin body 30 made of the silicone 30A or the epoxy 30B.

The second package unit 4 includes a second package resin body 40 formed on the at least one substrate body 10 to cover the first package resin body 30. The second package resin body 40 may be a light uniforming resin body having a light diffusing material mixed therein, and the second package resin body 40 has an exposed light uniforming surface 400 formed thereon. In addition, the second package resin body 40 is a light diffusing resin body formed by mixing silicon 40A and a plurality of light diffusing particles 40C or by mixing epoxy 40B and a plurality of light diffusing particles 40C according to different requirements, and the light diffusing particles 40C can be made of silicon dioxide or titanium dioxide. For example, liquid silicone having the light diffusing particles 40C or liquid epoxy having the light diffusing particles 40C can be formed on the at least one substrate body 10 to cover the first package resin body 30 by adhesive dripping or press molding, and then liquid silicone or liquid epoxy can be baked (or cured) to form the solidified second package resin body 40 formed by mixing the silicon 40A and the light diffusing particles 40C or by mixing the epoxy 40B and the light diffusing particles 40C. Moreover, the exposed light uniforming surface 400 may be a light uniforming curved surface.

Therefore, light beams L generated by the at least one light emitting element 20 can sequentially pass through the first package resin body 30 and the second package resin body 40 to form an uniform light emitting region 400′ on the exposed light uniforming surface 400. In other words, when the light beams L generated by the at least one light emitting element 20 passes through the second package resin body 40, the light beams L can be diffused by the light diffusing particles 40C. Hence, the user can see the uniform light emitting region 400′ formed on the exposed light uniforming surface 400 when the LED package structure Z is lighting.

### Second Embodiment

Referring to FIG. 2, where the second embodiment provides a LED package structure Z for increasing the light uniforming effect, comprising: a substrate unit 1, a light emitting unit 2, a first package unit 3, and a second package unit 4. Comparing FIG. 2 with FIG. 1, the difference between the second embodiment and the first embodiment is that: in the second embodiment, the second package resin body 40 is a light diffusing resin body formed by mixing silicon 40A, a plurality of first light diffusing particles 40D, and a plurality of second light diffusing particles 40E or by mixing epoxy 40B, a plurality of first light diffusing particles 40D, and a plurality of second light diffusing particles 40E. In addition, the first light diffusing particles 40D can be made of silicon dioxide or titanium dioxide, the second light diffusing particles 40E can be made of silicon dioxide or titanium dioxide, and the first light diffusing particle 40D and the second light diffusing particle 40E are two different light diffusing substances. Of course, the instant disclosure can use more than two types of light diffusing particles to mix with the silicone 40A or the epoxy 40B according to different requirements.

### Third Embodiment

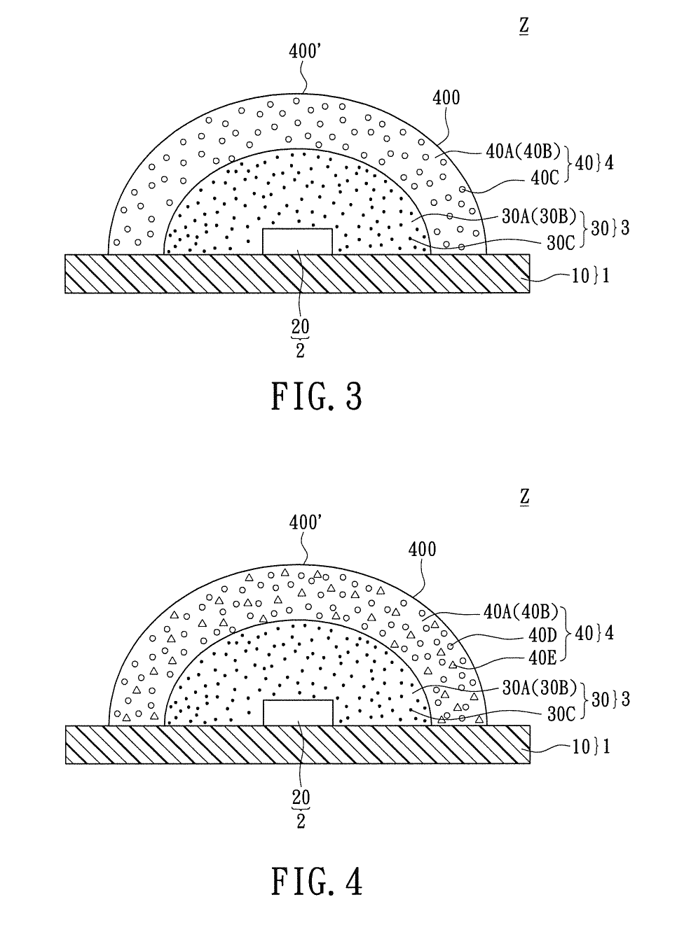

Referring to FIG. 3, where the third embodiment provides a LED package structure Z for increasing the light uniforming effect, comprising: a substrate unit 1, a light emitting unit 2, a first package unit 3, and a second package unit 4. Comparing FIG. 3 with FIG. 1, the difference between the third embodiment and the first embodiment is that: in the third embodiment, the first package resin body 30 is a phosphor resin body formed by mixing silicone 30A and a plurality of phosphor particles 30C or by mixing epoxy 30B and a plurality of phosphor particles 30C. Hence, when the light emitting element 20 is a blue LED chip, the LED package structure Z can generate white light source by the phosphor resin body having the phosphor particles 30C.

### Fourth Embodiment

Referring to FIG. 4, where the fourth embodiment provides a LED package structure Z for increasing the light uniforming effect, comprising: a substrate unit 1, a light emitting unit 2, a first package unit 3, and a second package unit 4. Comparing FIG. 4 with FIG. 3, the difference between the fourth embodiment and the third embodiment is that: in the fourth embodiment, the second package resin body 40 is a light diffusing resin body formed by mixing silicon 40A, a plurality of first light diffusing particles 40D, and a plurality of second light diffusing particles 40E or by mixing epoxy 40B, a plurality of first light diffusing particles 40D, and a plurality of second light diffusing particles 40E. In addition, the first light diffusing particles 40D can be made of silicon dioxide or titanium dioxide, the second light diffusing particles 40E can be made of silicon dioxide or titanium dioxide, and the first light diffusing particle 40D and the second light diffusing particle 40E are two different light diffusing substances. Of course, the instant disclosure can use more than two types of light diffusing particles to mix with the silicone 40A or the epoxy 40B according to different requirements.

### Fifth Embodiment

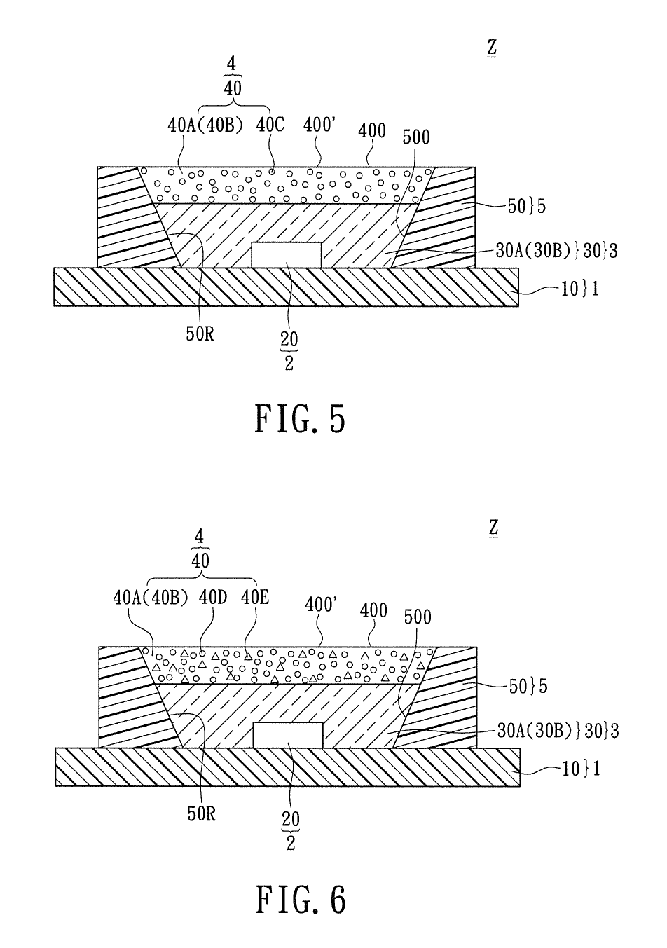

Referring to FIG. 5, where the fifth embodiment provides a LED package structure Z for increasing the light uniforming effect, comprising: a substrate unit 1, a light emitting unit 2, a first package unit 3, a second package unit 4, and a frame unit 5.

Furthermore, the substrate unit 1 includes at least one substrate body 10. The light emitting unit 2 includes at least one light emitting element 20 disposed on the at least one substrate body 10 and electrically connected to the at least one substrate body 10. The frame unit 5 includes a surrounding reflection frame body 50 surroundingly disposed on the at least one substrate body 10 to form a receiving space 50R. The surrounding reflection frame body 50 surrounds the at least one light emitting element 20, thus the at least one light emitting element 20 is received in the receiving space 50R. The first package unit 3 includes a first package resin body 30 formed on the at least one substrate body 10 to cover the at least one light emitting element 20, and the first package resin body 30 is received in the receiving space 50R of the surrounding reflection frame body 50. The second package unit 4 includes a second package resin body 40 received in the receiving space 50R of the surrounding reflection frame body 50 and disposed on the top surface of the first package resin body 30. The second package resin body 40 is a light uniforming resin body having a light diffusing material mixed therein, and the second package resin body 40 has an exposed light uniforming surface 400 formed thereon. Therefore, light beams L generated by the at least one light emitting element 20 can sequentially pass through the first package resin body 30 and the second package resin body 40 to form an uniform light emitting region 400′ on the exposed light uniforming surface 400.

Comparing to FIG. 5 with FIG. 1, the difference between the fifth embodiment and the first embodiment is that: the fifth embodiment further comprises a frame unit 5. In addition, the surrounding reflection frame body 50 has an inner reflection inclined surface 500 in the receiving space 50R to tightly contact the first package resin body 30 and the second package resin body 40, and the inner reflection inclined surface 500 is gradually outwardly expanded from bottom to top.

### Sixth Embodiment

Referring to FIG. 6, where the sixth embodiment provides a LED package structure Z for increasing the light uniforming effect, comprising: a substrate unit 1, a light emitting unit 2, a first package unit 3, a second package unit 4, and a frame unit 5. Comparing FIG. 6 with FIG. 5, the difference between the sixth embodiment and the fifth embodiment is that: in the sixth embodiment, the second package resin body 40 is a light diffusing resin body formed by mixing silicon 40A, a plurality of first light diffusing particles 40D, and a plurality of second light diffusing particles 40E or by mixing epoxy 40B, a plurality of first light diffusing particles 40D, and a plurality of second light diffusing particles 40E. In addition, the first light diffusing particles 40D can be made of silicon dioxide or titanium dioxide, the second light diffusing particles 40E can be made of silicon dioxide or titanium dioxide, and the first light diffusing particle 40D and the second light diffusing particle 40E are two different light diffusing substances. Of course, the instant disclosure can use more than two types of light diffusing particles to mix with the silicone 40A or the epoxy 40B according to different requirements.

### Seventh Embodiment

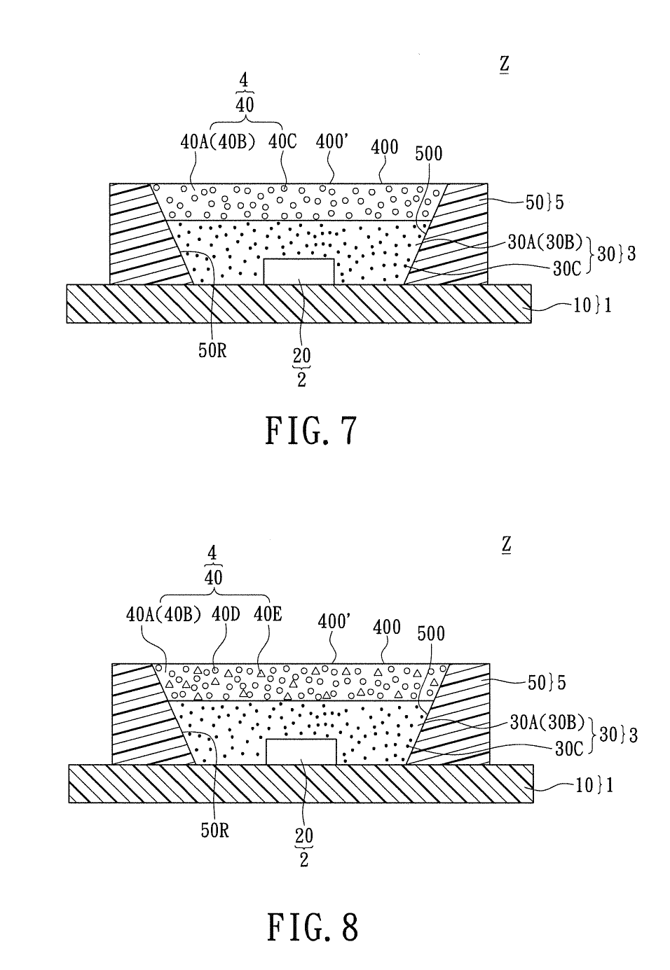

Referring to FIG. 7, where the seventh embodiment provides a LED package structure Z for increasing the light uniforming effect, comprising: a substrate unit 1, a light emitting unit 2, a first package unit 3, a second package unit 4, and a frame unit 5. Comparing FIG. 7 with FIG. 5, the difference between the seventh embodiment and the fifth embodiment is that: in the seventh embodiment, the first package resin body 30 is a phosphor resin body formed by mixing silicone 30A and a plurality of phosphor particles 30C or by mixing epoxy 30B and a plurality of phosphor particles 30C. Hence, when the light emitting element 20 is a blue LED chip, the LED package structure Z can generate white light source by the phosphor resin body having the phosphor particles 30C.

### Eighth Embodiment

Referring to FIG. 8, where the eighth embodiment provides a LED package structure Z for increasing the light uniforming effect, comprising: a substrate unit 1, a light emitting unit 2, a first package unit 3, a second package unit 4, and a frame unit 5. Comparing FIG. 8 with FIG. 7, the difference between the eighth embodiment and the seventh embodiment is that: in the eighth embodiment, the second package resin body 40 is a light diffusing resin body formed by mixing silicon 40A, a plurality of first light diffusing particles 40D, and a plurality of second light diffusing particles 40E or by mixing epoxy 40B, a plurality of first light diffusing particles 40D, and a plurality of second light diffusing particles 40E. In addition, the first light diffusing particles 40D can be made of silicon dioxide or titanium dioxide, the second light diffusing particles 40E can be made of silicon dioxide or titanium dioxide, and the first light diffusing particle 40D and the second light diffusing particle 40E are two different light diffusing substances. Of course, the instant disclosure can use more than two types of light diffusing particles to mix with the silicone 40A or the epoxy 40B according to different requirements.

In conclusion, because the second package resin body is a light uniforming resin body having a light diffusing material mixed therein, the light uniforming effect of the illumination generated from the LED package structure can be increased.

Furthermore, the first package resin body may be a transparent resin body formed by silicone or epoxy, or may be a phosphor resin body formed by mixing silicone and a plurality of phosphor particles or by mixing epoxy and a plurality of phosphor particles, according to different requirements. In addition, the second package resin body may be a light diffusing resin body formed by mixing silicon and a plurality of light diffusing particles or by mixing epoxy and a plurality of light diffusing particles, or may be a light diffusing resin body formed by mixing silicon, a plurality of first light diffusing particles, and a plurality of second light diffusing particles or by mixing epoxy, a plurality of first light diffusing particles, and a plurality of second light diffusing particles, according to different requirements.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A LED package structure for increasing the light uniforming effect, comprising:
a substrate unit including at least one substrate body;
a light emitting unit including at least one light emitting element disposed on the at least one substrate body and electrically connected to the at least one substrate body;
a first package unit including a first package resin body formed on the at least one substrate body to cover the at least one light emitting element; and
a second package unit including a second package resin body formed on the at least one substrate body to cover the first package resin body, wherein the second package resin body is a light uniforming resin body having a light diffusing material mixed therein, and the second package resin body has an exposed light uniforming surface formed thereon;
wherein, light beams generated by the at least one light emitting element sequentially pass through the first package resin body and the second package resin body to form an uniform light emitting region on the exposed light uniforming surface.

2. The LED package structure of claim 1, wherein the at least one substrate body is a circuit substrate, and the at least one light emitting element is a LED bare chip.

3. The LED package structure of claim 1, wherein the first package resin body is a transparent resin body formed by silicone or epoxy.

4. The LED package structure of claim 1, wherein the first package resin body is a phosphor resin body formed by mixing silicone and a plurality of phosphor particles or by mixing epoxy and a plurality of phosphor particles.

5. The LED package structure of claim 1, wherein the second package resin body is a light diffusing resin body formed by mixing silicon and a plurality of light diffusing particles or by mixing epoxy and a plurality of light diffusing particles.

6. The LED package structure of claim 5, wherein the light diffusing particles are made of silicon dioxide or titanium dioxide.

7. The LED package structure of claim 1, wherein the second package resin body is a light diffusing resin body formed by mixing silicon, a plurality of first light diffusing particles, and a plurality of second light diffusing particles or by mixing epoxy, a plurality of first light diffusing particles, and a plurality of second light diffusing particles.

8. The LED package structure of claim 7, wherein the first light diffusing particles are made of silicon dioxide or titanium dioxide, the second light diffusing particles are made of silicon dioxide or titanium dioxide, and the first light diffusing particle and the second light diffusing particle are two different light diffusing substances.

9. The LED package structure of claim 1, wherein the exposed light uniforming surface is a light uniforming curved surface.

10. A LED package structure for increasing the light uniforming effect, comprising:
a substrate unit including at least one substrate body;
a light emitting unit including at least one light emitting element disposed on the at least one substrate body and electrically connected to the at least one substrate body;
a frame unit including a surrounding reflection frame body surroundingly disposed on the at least one substrate body to form a receiving space, wherein the surrounding reflection frame body surrounds the at least one light emitting element, thus the at least one light emitting element is received in the receiving space;
a first package unit including a first package resin body formed on the at least one substrate body to cover the at least one light emitting element, wherein the first package resin body is received in the receiving space of the surrounding reflection frame body; and
a second package unit including a second package resin body received in the receiving space of the surrounding reflection frame body and disposed on the top surface of the first package resin body, wherein the second package resin body is a light uniforming resin body having a light diffusing material mixed therein, and the second package resin body has an exposed light uniforming surface formed thereon;
wherein, light beams generated by the at least one light emitting element sequentially pass through the first package resin body and the second package resin body to form an uniform light emitting region on the exposed light uniforming surface.

11. The LED package structure of claim 10, wherein the at least one substrate body is a circuit substrate, and the at least one light emitting element is a LED bare chip.

12. The LED package structure of claim 10, wherein the first package resin body is a transparent resin body formed by silicone or epoxy.

13. The LED package structure of claim 10, wherein the first package resin body is a phosphor resin body formed by mixing silicone and a plurality of phosphor particles or by mixing epoxy and a plurality of phosphor particles.

14. The LED package structure of claim 10, wherein the second package resin body is a light diffusing resin body formed by mixing silicon and a plurality of light diffusing particles or by mixing epoxy and a plurality of light diffusing particles.

15. The LED package structure of claim 14, wherein the light diffusing particles are made of silicon dioxide or titanium dioxide.

16. The LED package structure of claim 10, wherein the second package resin body is a light diffusing resin body formed by mixing silicon, a plurality of first light diffusing particles, and a plurality of second light diffusing particles or by mixing epoxy, a plurality of first light diffusing particles, and a plurality of second light diffusing particles.

17. The LED package structure of claim 16, wherein the first light diffusing particles are made of silicon dioxide or titanium dioxide, the second light diffusing particles are made of silicon dioxide or titanium dioxide, and the first light diffusing particle and the second light diffusing particle are two different light diffusing substances.

18. The LED package structure of claim 10, wherein the exposed light uniforming surface is a light uniforming curved surface.

19. The LED package structure of claim 10, wherein the surrounding reflection frame body has an inner reflection inclined surface in the receiving space to tightly contact the first package resin body and the second package resin body, and the inner reflection inclined surface is gradually outwardly expanded from bottom to top.
